(19) United States
(12) Patent Application Publication
(10) Pub. No.: US 2024/0110943 A1
(43) Pub. Date: Apr. 4, 2024

(54) METHODS OF REINFORCING PLATED METAL STRUCTURES AND MODULATING MECHANICAL PROPERTIES USING NANO-FIBERS

(71) Applicant: Microfabrica Inc., Van Nuys, CA (US)

(72) Inventor: Onnik Yaglioglu, Chatsworth, CA (US)

(21) Appl. No.: 18/540,446

(22) Filed: Dec. 14, 2023

Related U.S. Application Data
(63) Continuation of application No. 17/464,612, filed on Sep. 1, 2021.
(60) Provisional application No. 63/075,066, filed on Sep. 4, 2020.
(60) Provisional application No. 63/073,380, filed on Sep. 1, 2020.

(51) Int. Cl. G01R 1/067; G01R 1/073; H01R 13/03

(52) U.S. Cl. CPC G01R 1/06716; G01R 1/06755; G01R 1/06761; G01R 1/07342; H01R 13/03; H01R 13/2407; H01R 2201/20

(57) ABSTRACT

Probe structures, probe arrays) and methods for making such structures include incorporation of nano-fibers and metal composites to provide structures with improved material properties. Nano-fiber incorporation may occur by co-deposition of fibers and metal, selective placement of fibers followed by deposition of metal, or general placement of fibers followed by selective deposition of a metal. Structures may be formed from single layers of fibers and deposited metal or from multiple layers formed adjacent to one another or attached to one another after formation. All portions, or only selected portions, of a structure may include composites of metal and nano-fibers.

### CROSS-REFERENCE TO RELATED APPLICATION(S)

This application is a continuation of U.S. patent application Ser. No. 17/464,612, filed Sep. 1, 2021, titled “Methods of Reinforcing Plated Metal Structures and Independently Modulating Mechanical Properties Using Nano-Fibers,” which claims priority to and the benefit of U.S. Provisional Application No. 63/073,380, filed Sep. 1, 2020, and U.S. Provisional Application No. 63/075,066, filed Sep. 4, 2020, the contents of which are incorporated herein by reference in their entirety.

### TECHNICAL FIELD

The present invention relates generally to the field of plated metal structures and more particularly, in some embodiments, to methods of forming probe arrays or subarrays for testing (e.g. wafer level testing or socket testing) of electronic components (e.g. integrated circuits), and even more particularly, the formation of such arrays or subarrays to allow independent modulation of selected material properties by incorporating nano-fibers during plating into at least some portions of the probe structures.

### BACKGROUND

Probes:

Numerous electrical contact probe and pin configurations as well as array formation methods have been commercially used or proposed, some of which may be prior art while others are not. Examples of such pins, probes, arrays, and methods of making are set forth in the following patent applications, publications of applications, and patents. Each of these applications, publications, and patents is incorporated herein by reference as if set forth in full herein as are any teachings set forth in each of their prior priority applications.

| U.S. patent application Ser. | |
|---|---|
| No., Filing Date | |
| U.S. App Pub No., Pub Date | |
| U.S. Pat. No., Pub Date | First Named Inventor, “Title” |
| 10/772,943 - Feb. 4, 2004 | Arat, et al., “Electrochemically |
| 2005-0104609 - May 19, 2005 | Fabricated Microprobes” |
| -- | |
| 10/949,738 - Sep. 24, 2004 | Kruglick, et al., “Electrochemically |
| 2006-0006888 - Jan. 12, 2006 | Fabricated Microprobes” |
| -- | |
| 11/028,945 - Jan. 3, 2005 | Cohen, et al., “A Fabrication Process for |
| 2005-0223543 - Oct. 13, 2005 | Co-Fabricating a Multilayer Probe Array |
| 7,640,651 - Jan. 5, 2010 | and a Space Transformer |
| 11/028,960 - Jan 3, 2005 | Chen, et al. “Cantilever Microprobes for |
| 2005-0179458 - Aug. 18, 2005 | Contacting Electronic Components and |
| 7,265,565 - Sep. 4, 2007 | Methods for Making Such Probes |
| 11/029,180 - Jan. 3, 2005 | Chen, et al. “Pin-Type Probes for |
| 2005-0184748 - Aug. 25, 2005 | Contacting Electronic Circuits and |
| -- | Methods for Making Such Probes” |
| 11/029,217 - Jan. 3, 2005 | Kim, et al., “Microprobe Tips and |
| 2005-0221644 - Oct. 6, 2005 | Methods for Making” |
| 7,412,767 - Aug. 19, 2008 | |
| 11/173,241 - Jun. 30, 2005 | Kumar, et al., Probe Arrays and Method |
| 2006-0108678 - May 25, 2006 | for Making |
| -- | |
| 11/178,145 - Jul. 7, 2005 | Kim, et al., “Microprobe Tips and |
| 2006-0112550 - Jun. 1, 2006 | Methods for Making” |
| 7,273,812 - Sep. 25, 2007 | |
| 11/325,404 - Jan. 3, 2006 | Chen, et al., “Electrochemically |
| 2006-0238209 - Oct. 26, 2006 | Fabricated Microprobes” |
| -- | |
| 14/986,500 - Dec. 31, 2015 | Wu, et al. “Multi-Layer, Multi-Material |
| 2016-0231356 - Aug. 11, 2016 | Micro-Scale and Millimeter-Scale |
| 10,215,775 - Feb. 26, 2019 | Devices with Enhanced Electrical and/or |
| | Mechanical Properties” |
| 16/584,818 - Sep. 26, 2019 | Smalley, “Probes Having Improved |
| 11,262,383 - Mar. 1, 2022 | Mechanical and/or Electrical Properties |
| | for Making Contact between Electronic |
| | Circuit Elements and Methods for |
| | Making” |
| 16/584,863 - Sep. 26, 2019 | Frodis, “Probes Having Improved |
| (P-US377-A-MF) | Mechanical and/or Electrical Properties |
| | for Making Contact between Electronic |
| | Circuit Elements and Methods for |
| | Making” |
| 17/139,933 - Dec. 31, 2020 | Wu, “Compliant Pin Probes with |
| 11,802,891 - Oct. 31, 2023 | Multiple Spring Segments and |
| | Compression Spring Deflection |
| | Stabilization Structures, Methods for |
| | Making, and Methods for Using” |
| 17/139,936 - Dec. 31, 2020 | Wu, “Probes with Multiple Springs, |
| (P-US400-A-MF) | Methods for Making, and Methods for |
| | Using” |
| 17/139,940 - Dec. 31, 2020 | Wu, “Compliant Pin Probes with Flat |
| (P-US401-A-MF) | Extension Springs, Methods for Making, |
| | and Methods for Using” |
| 16/791,288 - Feb. 14, 2020 | Frodis, “Multi-Beam Vertical Probes |
| (P-US385-A-MF) | with Independent Arms Formed of a |
| | High Conductivity Metal for Enhancing |
| | Current Carrying Capacity and Methods |
| | for Making Such Probes” |
| 17/139,925 - Dec. 31, 2020 | Veeramani, “Probes with Planar |
| 11,625,904 - Apr. 11, 2023 | Unbiased Spring Elements for Electronic |
| | Component Contact and Methods for |
| | Making Such Probes” |
| 17/240,962 - Apr. 26, 2021 | Lockard, “Buckling Beam Probe Arrays |
| 11,821,918 - Nov. 21, 2023 | and Methods for Making Such Arrays |
| | Including Forming Probes with Lateral |
| | Positions Matching Guide Plate Hole |
| | Positions” |
| 17/384,680 - Jul. 23, 2021 | Yaglioglu, “Methods for Making Probe |
| (P-US407-A-MF) | Arrays Utilizing Lateral Plastic |
| | Deformation of Probe Preforms” |
| 17/390,835 - Jul. 30, 2021 | Yaglioglu, “Methods for Making Probe |
| (P-US408-A-MF) | Arrays Utilizing Deformed Templates” |
| 17/401,252 - Aug. 12, 2021 | Lockard, et al., “Probe Arrays and |
| (P-US409-A-MF) | Improved Methods for Making and |
| | Using Longitudinal Deformation of |
| | Probe Preforms” |

As the pitch requirements of probing applications get more demanding, i.e. as pitches get smaller, achieving the required contact force without exceeding the yield stress of the material used becomes increasingly challenging, and as such, a need exists for methods for creating probe arrays allowing independent control of material properties so that such requirements can be met.

### SUMMARY

It is a first object of some embodiments of the invention to provide an improved method of forming a probe array incorporating probes that have selected mechanical properties independently manipulated during formation of at least portions of the probes.

It is a second object of some embodiments of the invention to provide an improved method of forming probe arrays that incorporate nano-fibers into at least portions of the probes as they are formed.

It is a third object of some embodiments of the invention to provide improved probes and probe arrays.

Other objects and advantages of various embodiments of the invention will be apparent to those of skill in the art upon review of the teachings herein. The various embodiments of the invention, set forth explicitly herein or otherwise ascertained from the teachings herein, may address one or more of the above objects alone or in combination, or alternatively may address some other object ascertained from the teachings herein. It is not intended that all objects, or even multiple objects, be addressed by any single aspect or embodiment of the invention even though that may be the case regarding some aspects.

In a first aspect of the invention, a probe is provided, including: (a) an elastically deformable body portion having a first end and a second end; (b) a first contact region connected directly or indirectly to the first end, wherein the first contact region is configured for a function selected from the group consisting of: (1) making temporary pressure based electrical contact to a first electronic component upon elastically biasing the deformable body with the first contact region against the first electronic component, and (2) bonding to the first electronic component for making permanent contact; and (c) a second contact region connected directly or indirectly to the second end, wherein the second contact region is configured for making temporary pressure based electrical contact to a second electronic component upon elastically biasing the deformable body with the second contact region against the second electronic component, wherein the elastically deformable body includes a plurality of nano-fibers embedded in a structural metal.

Numerous variations of the first aspect of the invention are possible and include, for example: (1) the nano-fibers including a material selected from the group consisting of: (i) metal nanorods, (ii) nanotubes, and (iii) carbon nanotubes; (2) the probe additionally including a plurality of adhered layers; (3) the first contact region being configured for bonding to the first electronic component for making permanent contact; and (4) the first contact region being configured for making temporary contact.

In a second aspect of the invention, a probe array is provided, including: (a) a plurality of probes, including: (i) an elastically deformable body portion having a first end and a second end; (ii) a first contact region connected directly or indirectly to the first end, wherein the first contact region is configured for a function selected from the group consisting of: (1) making temporary pressure based electrical contact to a first electronic component upon elastically biasing the deformable body with the first contact region against the first electronic component, and (2) bonding to the first electronic component for making permanent contact; and (iii) a second contact region connected directly or indirectly to the second end, wherein the second contact region is configured for making temporary pressure based electrical contact to a second electronic component upon elastically biasing the deformable body with the second contact region against the second electronic component, wherein the elastically deformable body includes a plurality of nano-fibers embedded in a structural metal, and (b) at least one probe array retention structure selected from the group consisting of: (i) a substrate to which the first contact regions of the probes are bonded; (ii) a substrate to which the first contact regions of the probes are bonded along with at least one guide plate having a plurality of holes which engage the probes are inserted wherein the holes in the guide plate are laterally aligned with bonding locations on the substrate; (iii) a substrate to which the first contact regions of the probes are bonded along with at least one guide plate having a plurality of holes which engage the probes wherein the holes in at least one of the at least one guide plate are laterally shifted relative to the bonding locations on the substrate; (iv) a plurality of guide plates each having a plurality of holes which engage the probes; (v) a plurality of guide plates each having a plurality of holes which engage the probes, wherein at least two of the plurality of guide plates have holes that engage probes that are laterally aligned; and (vi) a plurality of guide plates each having a plurality of holes which engage the probes, wherein at least two of the plurality of guide plates have holes that engage probes that are laterally shifted with respect to one another; and (vii) a retaining structure or alignment structure into which the probes are inserted wherein the retaining structure or alignment structure has thickness selected from the group consisting of: (1) at least ¼ of a longitudinal length of the probes from first contact region to second contact region; (2) (1) at least ½ of a longitudinal length of the probes from first contact region to second contact region; (1) at least ¾ of a longitudinal length of the probes from first contact region to second contact region.

Numerous variations of the second aspect of the invention are possible and include, for example: (1) the fibers including a material selected from the group consisting of: (i) metal nanorods, (ii) nanotubes, and (iii) carbon nanotubes; (2) the probe array further including a plurality of adhered layers; (3) the first contact region being configured for bonding to the first electronic component for making permanent contact; and (4) the first contact region being configured for making temporary contact.

In a third aspect of the invention, a method of forming a probe is provided, including: (a) providing a substrate; and (b) providing a patterned composite structural material including at least one structural metal and a plurality of nano-fibers, wherein the providing of the composite structural material includes a method selected from the group consisting of: (i) forming a plating template with at least one opening and then simultaneously co-depositing nano-fibers and a structural metal into the at least one opening; (ii) forming a plating template with at least one opening and then simultaneously co-depositing nano-fibers and a structural metal wherein nano-fiber properties (e.g. distribution, average size, size distribution, and/or material composition) within a plating solution are maintained at a substantially uniform level during the co-depositing to provide uniform properties to a resulting structural material; (iii) forming a plating template with at least one opening and then simultaneously co-depositing nano-fibers and a structural metal wherein fiber properties within a plating solution are varied during the co-depositing to cause varied properties within a resulting structural material; (iv) forming a plating template with at least one opening and then co-depositing the nano-fibers and the structural metal according to any of (i)-(iii), and then planarizing the deposited material; (v) forming a plating template with at least one opening and then locating a plurality of nano-fibers into the at least one opening and thereafter depositing at least one structural metal into the at least one opening; (vi) forming a plating template with at least one opening and then locating a plurality of longitudinally oriented nano-fibers into the at least one opening and thereafter depositing at least one structural metal into the at least one opening; (vii) forming a plating template with at least one opening and then growing a plurality of nano-fibers in the at least one opening and thereafter depositing at least one structural metal into the at least one opening; (viii) forming a plating template with at least one opening and then growing a plurality of longitudinally oriented nano-fibers in the opening and thereafter depositing at least one structural metal into the at least one opening; (ix) forming a plating template with at least one opening and then locating or growing the nano-fibers and depositing the structural metal according to any of (v)-(viii), and then planarizing the deposited material; (x) locating a plurality of nano-fibers directly or indirectly on a substrate then forming a patterned plating template with at least one opening that contains a plurality of nano-fibers and thereafter depositing at least one structural metal into the at least one opening, and thereafter removing the plating template along with at least a portion of any nano-fibers that were not held by the deposited structural metal; (xi) locating a plurality of longitudinally oriented nano-fibers directly or indirectly on a substrate, then forming a patterned plating template with at least one opening that contains a plurality of the nano-fibers, thereafter depositing at least one structural metal into the at least one opening, and thereafter removing the plating template along with at least a portion of any nano-fibers that were not held by the deposited structural metal; (xii) growing a plurality of nano-fibers directly or indirectly on a substrate, then forming a patterned plating template with at least one opening that contains a plurality of nano-fibers, thereafter depositing at least one structural metal into the at least one opening, and thereafter removing the plating template along with at least a portion of any nano-fibers that were not held by the deposited structural metal; (xiii) growing a plurality of longitudinally oriented nano-fibers directly or indirectly on a substrate, then forming a patterned plating template with at least one opening that contains a plurality of nano-fibers, thereafter depositing at least one structural metal into the at least one opening, and thereafter removing the plating template along with at least a portion of any nano-fibers that were not held by the deposited structural metal; and (xiv) forming a plating template, locating or growing the nano-fibers, depositing the structural metal within the at least one opening, and thereafter planarizing the deposited material; wherein the probe includes: (1) an elastically deformable body portion including the composite material and having a first end and a second end; (2) a first contact region connected directly or indirectly to the first end, wherein the first contact region is configured for a function selected from the group consisting of: (1) making temporary pressure based electrical contact to a first electronic component upon elastically biasing the deformable body with the first contact region against the first electronic component, and (2) bonding to the first electronic component for making permanent contact; and (3) a second contact region connected directly or indirectly to the second end, wherein the second contact region is configured for making temporary pressure based electrical contact to a second electronic component upon elastically biasing the deformable body with the second contact region against the second electronic component.

Numerous variations of the third aspect of the invention are possible and include, for example: (1) the nano-fibers including a material selected from the group consisting of: (i) metal nanorods, (ii) nanotubes, and (iii) carbon nanotubes; (2) the method additionally including forming a plurality of adhered layers; (3) the first contact region being configured for bonding to the first electronic component for making permanent contact; and (4) the first contact region being configured for making temporary contact.

In a fourth aspect of the invention, a method of forming a probe array is provided, including: (a) forming a plurality of probes, including: (i) providing a build substrate; and (ii) providing a patterned composite structural material including at least one structural metal and a plurality of nano-fibers, wherein the providing of the composite structural material includes a method selected from the group consisting of: (A) forming a plating template with a plurality of openings and then simultaneously co-depositing nano-fibers and a structural metal into the plurality of openings; (B) forming a plating template with a plurality of openings and then simultaneously co-depositing nano-fibers and a structural metal wherein fiber properties (e.g. distribution, average size, size distribution, and/or material composition) within a plating solution are maintained at a substantially uniform level during the co-depositing to provide uniform properties to a resulting structural material; (C) forming a plating template with a plurality of openings and then simultaneously co-depositing nano-fibers and a structural metal wherein fiber properties within a plating solution are varied during the co-depositing to cause varying properties within a resulting structural material; (D) forming a plating template with a plurality of openings and then co-depositing the nano-fibers and the structural metal according to any of (i)-(iii), and then planarizing the deposited material; (E) forming a plating template with a plurality of openings and then locating a plurality of nano-fibers into the plurality of openings and thereafter depositing at least one structural metal into the at least one opening; (F) forming a plating template with a plurality of openings and then locating a plurality of longitudinally oriented nano-fibers into the plurality of openings and thereafter depositing at least one structural metal into the at least one opening; (G) forming a plating template with a plurality of openings and then growing a plurality of nano-fibers in the plurality of openings and thereafter depositing at least one structural metal into the plurality of openings; (H) forming a plating template with a plurality of openings and then growing a plurality of longitudinally oriented nano-fibers in the plurality of openings and thereafter depositing at least one structural metal into the plurality of openings; (I) forming a plating template with a plurality of openings and then locating or growing the nano-fibers and depositing the structural metal according to any of (E)-(H), and then planarizing the deposited material; (J) locating a plurality of nano-fibers directly or indirectly on a substrate, then forming a patterned plating template with a plurality of openings that contains a plurality of nano-fibers, thereafter depositing at least one structural metal into the plurality of openings, and thereafter removing the plating template along with at least a portion of any nano-fibers that were not held by the deposited structural metal; (K) locating a plurality of longitudinally oriented nano-fibers directly or indirectly on a substrate, then forming a patterned plating template with a plurality of openings that contains a plurality of nano-fibers, thereafter depositing at least one structural metal into the plurality of openings, and thereafter removing the plating template along with at least a portion of any nano-fibers that were not held by the deposited structural metal; (L) growing a plurality of nano-fibers directly or indirectly on a substrate, then forming a patterned plating template with a plurality of openings that contains a plurality of nano-fibers, thereafter depositing at least one structural metal into the plurality of openings, and thereafter removing the plating template along with at least a portion of any nano-fibers that were not held by the deposited structural metal; (M) growing a plurality of longitudinally oriented nano-fibers directly or indirectly on a substrate, then forming a patterned plating template with a plurality of openings that contains a plurality of nano-fibers, thereafter depositing at least one structural metal into the plurality of openings, and thereafter removing the plating template along with at least a portion of any nano-fibers that were not held by the deposited structural metal; and (N) forming a plating template, locating or growing the nano-fibers, depositing the structural metal within the plurality of openings, and thereafter planarizing the deposited material; wherein each of the plurality of probes includes: (1) an elastically deformable body portion having a first end and a second end; (2) a first contact region connected directly or indirectly to the first end, wherein the first contact region is configured for a function selected from the group consisting of: (1) making temporary pressure based electrical contact to a first electronic component upon elastically biasing the deformable body with the first contact region against the first electronic component, and (2) bonding to the first electronic component for making permanent contact; and (3) a second contact region connected directly or indirectly to the second end, wherein the second contact region is configured for making temporary pressure based electrical contact to a second electronic component upon elastically biasing the deformable body with the second contact region against the second electronic component, wherein the elastically deformable body includes a plurality of nano-fibers embedded in a structural metal; and (b) providing at least one probe array retention structure and configuring the probes and at least one retention structure according to a process selected from the group consisting of: (i) providing a retention structure comprising a probe substrate to which the first contact regions of the probes are bonded, wherein the probe substrate includes the build substrate; (ii) providing a retention structure comprising a probe substrate and bonding the first contact regions of the probes to the probe substrate wherein the probe substrate and the build substrate are different; (iii) providing a retention structure including a probe substrate to which the first contact regions of the probes are bonded wherein the probe substrate includes the build substrate; (iv) providing a retention structure including a probe substrate and bonding the first contact regions of the probes to the probe substrate wherein the probe substrate and build substrate are different, and providing at least at least one guide plate having a plurality of holes that engage the probes; (v) providing a retention structure including a probe substrate and bonding the first contact regions of the probes to the probe substrate wherein the probe substrate and build substrate are different, and providing at least at least one guide plate having a plurality of holes and inserting the probes into the holes in the guide plate wherein holes in the guide plate are laterally aligned with bonding locations on the substrate; (vi) providing a retention structure including a probe substrate and bonding the first contact regions of the probes to the probe substrate wherein the probe substrate and build substrate are different, and providing at least at least one guide plate having a plurality of holes and inserting the probes into the holes in the guide plate, and laterally shifting the guide plate and the substrate so that holes in the guide plate are laterally shifted with respect to bonding locations on the substrate; (vii) providing a plurality of retention structures including a plurality of guide plates each having a plurality of holes which engage the probes; (viii) providing a plurality of retention structures including a plurality of guide plates each having a plurality of holes and engaging the probes with holes in at least one of the guide plates; (ix) providing a plurality of retention structures including a plurality of guide plates each having a plurality of holes which engage the probes, wherein at least two of the plurality of guide plates have holes that engage probes that are laterally aligned; (x) providing a plurality of retention structures including a plurality of guide plates each having a plurality of holes and engaging the probes with holes in at least one of the guide plates, wherein at least two of the plurality of guide plates have holes that engage probes that are laterally aligned; (xi) providing a plurality of retention structures including a plurality of guide plates each having a plurality of holes which engage the probes, wherein at least two of the plurality of guide plates have holes that engage probes that are laterally shifted with respect to one another; (xii) providing a plurality of retention structures including a plurality of guide plates each having a plurality of holes which engage the probes, and laterally shifting at least two of the plurality of guide plates respectively so that holes that engage probes in the two guide plates are laterally shifted with respect to one another; (xiii) providing a plurality of retention structures including a plurality of guide plates each having a plurality of holes and engaging the probes with the holes in at least one of the guide plates, wherein at least two of the plurality of guide plates have holes that engage probes that are laterally shifted with respect to one another; (xiv) providing a plurality of retention structures including a plurality of guide plates each having a plurality of holes and engaging the probes with the holes in at least one of the guide plates, and laterally shifting at least two of the plurality of guide plates respectively so that holes that engage probes in the two guide plates are laterally shifted with respect to one another; and (xv) providing a retaining structure or alignment structure with a plurality of opening for receiving probes and inserting the probes into the plurality of openings wherein the retaining structure or alignment structure has thickness selected from the group consisting of: (1) at least ¼ of a longitudinal length of the probes from first contact region to second contact region; (2) (1) at least ½ of a longitudinal length of the probes from first contact region to second contact region; (1) at least ¾ of a longitudinal length of the probes from first contact region to second contact region.

Numerous variations of the fourth aspect of the invention are possible and include, for example: (1) the nano-fibers including a material selected from the group consisting of: (i) metal nanorods, (ii) nanotubes, and (iii) carbon nanotubes; (2) the method additionally including forming a plurality of adhered layers; (3) the first contact region being configured for bonding to the first electronic component for making permanent contact; and (4) the first contact region being configured for making temporary contact.

Other aspects of the invention will be understood by those of skill in the art upon review of the teachings herein and for example may include alternatives in the configurations or processes set forth herein, decision branches noted in those processes or configurations, or partial or complete exclusion of such alternatives and/or decision branches in favor of explicitly setting forth process steps or features along with orders to be used in performing such steps or connections between such features. Some aspects may provide device counterparts to method of formation aspects, some aspects may provide method of formation counterparts to device aspects, and other aspects may provide for methods of use for the probe arrays provided herein.

### BRIEF DESCRIPTION OF THE DRAWINGS

FIGS. 1A-1F schematically depict the formation of a first layer of a structure using adhered mask plating where the blanket deposition of a second material overlays both the openings between deposition locations of a first material and the first material itself.

FIG. 1G depicts the completion of formation of the first layer resulting from planarizing the deposited materials to a desired level.

FIGS. 1H and 1I respectively depict the state of the process after formation of the multiple layers of the structure and after release of the structure from the sacrificial material.

FIG. 2A provides a cut view of multiple openings in a photoresist that forms a plating template while FIG. 2B provides a cut view of the openings in the plating template and a composite material including co-plated metal and nano-fibers that form composite structures or portions of a composite structures (e.g. probes).

FIGS. 2C1-2C5 illustrate side views of example probe arrays including probes of the type shown in FIG. 2B using different types of guide and/or mounting structures.

FIG. 3A provides a view of multiple openings in a photoresist template that have received or have had created therein strands of fibers while FIG. 3B provides a view of the same opening after they have received an electroplated metal to form a plurality of composite structures or portions of a plurality of structures.

FIGS. 3C1-3C5 illustrate side views of example probe arrays including probes of the type shown in FIG. 3B using different types of guide and/or mounting structures.

### DETAILED DESCRIPTION

Electrochemical Fabrication in General

Various implementations of the present invention may use single or multi-layer electrochemical deposition processes that are similar to those set forth in U.S. Pat. No. 6,027,630, issued on Feb. 22, 2000 to Adam Cohen or in U.S. Pat. No. 5,190,637 to Henry Guckel.

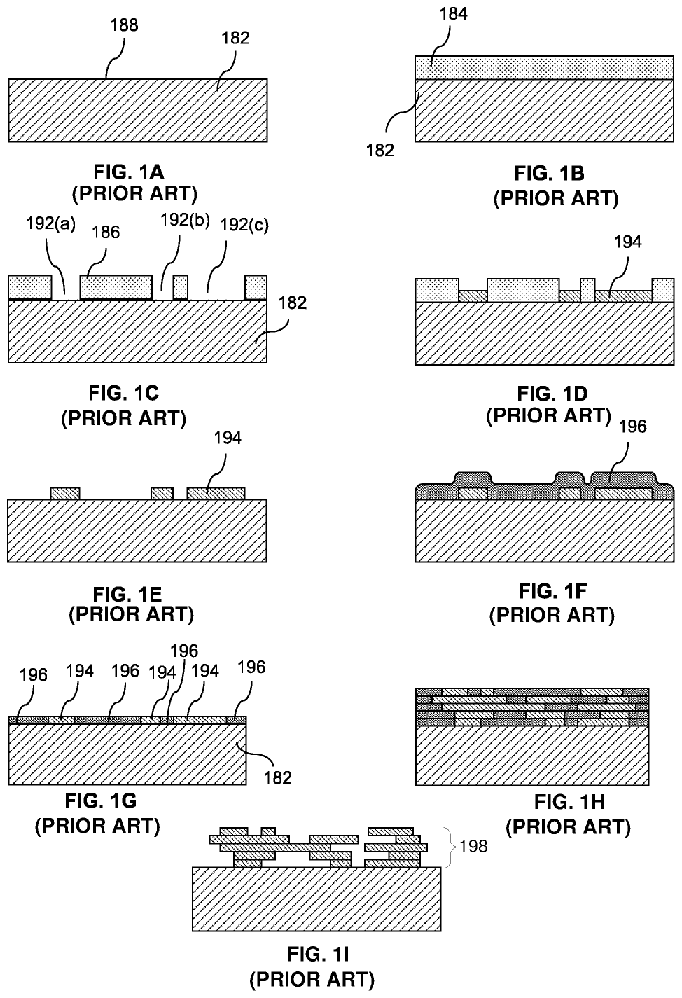

FIGS. 1A-1I are provided to illustrate techniques that may be useful. FIGS. 1A-1I illustrate side views of various states in an example multi-layer, multi-material electrochemical fabrication process. FIGS. 1A-1G illustrate various stages in the formation of a single layer of a multi-layer fabrication process where a second metal is deposited on a first metal as well as in openings in the first metal so that the first and second metals form part of the layer. In FIG. 1A, a side view of a substrate 182 having a surface 188 is shown, onto which patternable photoresist 184 is deposited, spread, or cast as shown in FIG. 1B. In FIG. 1C, a pattern of resist is shown that results from the curing, exposing, and developing of the resist. The patterning of the photoresist 184 results in openings or apertures 192(a)-192(c) extending from a surface 186 of the photoresist through the thickness of the photoresist to surface 188 of the substrate 182. In FIG. 1D, a metal 194 (e.g. nickel) is shown as having been electroplated into the openings 192(a)-192(c). In FIG. 1E, the photoresist has been removed (i.e. chemically stripped) from the substrate to expose regions of the substrate 182 which are not covered with the first metal 194. In FIG. 1F, a second metal 196 (e.g. silver) is shown as having been blanket electroplated over the entire exposed portions of the substrate 182 (which is conductive) and over the first metal 194 (which is also conductive). FIG. 1G depicts the completed first layer of the structure which has resulted from the planarization of the first and second metals down to a height that exposes the first metal and sets a thickness for the first layer. In FIG. 1H, the result of repeating the process steps shown in FIGS. 1B-1G several times to form a multi-layer structure is shown where each layer consists of two materials. For most applications, one of these materials is removed as shown in FIG. 1I to yield a desired 3-D structure 198 (e.g. component or device).

### Some Definitions

Definitions of various terms and concepts that may be used in understanding the embodiments of the invention (either for the devices or structures themselves, certain methods for making the devices or structures, or certain methods for using the devices or structures) will be understood by those of skill in the art. Some such terms and concepts are discussed herein while other such terms are addressed in the various patent applications to which the present application claims priority and/or which are incorporated herein by reference. Additional definitions and information about electrochemical fabrication methods may be found in a number of the various applications incorporated herein by reference such as, for example, U.S. patent application Ser. No. 16/584,818, filed Sep. 26, 2019 and entitled “Probes Having Improved Mechanical and/or Electrical Properties for Making Contact Between Electronic Circuit Elements and Methods for Making”.

The term “longitudinal” as used herein refers to a long dimension of a probe, an end-to-end dimension of the probe, or a tip-to-tip dimension. Longitudinal may refer to a generally straight line that extends from one end of the probe to another end of the probe or it may refer to a curved or stair-stepped path that has a sloped or even changing direction along a height of the probe. When referring to probe arrays, the longitudinal dimension may refer to a particular direction the probes in the array point or extend but it may also simply refer to the overall height of the array that starts at a plane containing a first end, tip, or base of a plurality of probes and extends perpendicular thereto to a plane containing a second end, tip, or top of the probes. The context of use typically makes clear what is meant especially to those of skill in the art. It is intended that the interpretation to be applied to the term herein be as narrow as warranted by the details of the description provided or the context in which the term is used. If however, no such narrow interpretation is warranted, it is intended that the broadest reasonable scope of interpretation apply.

The term “lateral” as used herein is related to the term longitudinal. In terms of the stacking of layers, lateral refers to a direction within each layer, or two perpendicular directions within each layer (i.e. one or more directions that lie within a plane of a layer that are substantially perpendicular to the longitudinal direction). When referring to probe arrays laterally generally has a similar meaning in that a lateral dimension is generally a dimension that lies in a plane that is parallel to a plane of the top or bottom of the array (i.e. substantially perpendicular to the longitudinal dimension. When referring to probes themselves, the lateral dimensions may be those that are perpendicular to an overall longitudinal axis of the probe, a local longitudinal axis of the probe (that is local lateral dimensions), or simply the dimensions similar to those noted for arrays or layers. The context of use typically makes clear what is meant especially to those of skill in the art. It is intended that the interpretation to be applied to the term herein be as narrow as warranted by the details of the description provided or the context in which the term is used. If no such narrow interpretation is warranted, it is intended that the broadest reasonable scope of interpretation apply.

When referring to longitudinal or lateral, the term substantially means within a particular angular orientation of the longitudinal or a lateral direction wherein the angle may be within 1°, within 2°, within 5°, or in some cases, within 10° depending on the context.

Probe and Probe Array Formation Embodiments:

Embodiments of the invention include reinforcement of plated metal structures using nano-fibers (e.g. metal nanorods, nanotubes, carbon nanotubes, metal oxide nanofibers (e.g., ZnO or Ti₂O), conductive nanofibers, insulating nanofibers, semiconductor nanofibers, etc.). In some embodiments, the nano-fibers or nanotubes can be formed as part of the plating process while in others, they can be fabricated before the plating step.

In a first group of embodiments, probes may be formed vertically or on their sides with plating occurring using a plating solution with nano-fibers dispersed therein. The plating processes may take the form noted in the various patent applications incorporated herein by reference and may be used to form probes having configurations similar to those noted in those applications or in other applications incorporated herein by references. In this first group of embodiments, step one includes dispersing nano-fibers into one or more plating solutions that will be used in forming the structural portions of the probes and, in particular, used in the spring portions of the probes. Step two involves the co-deposition of metal and the nano-fiber using the plating solution, either in a blanket manner or in selectively manner such that the nano-fibers and plated metal will be incorporated into the structures, probes, or springs. In addition to incorporating nano-fibers to aid in setting probe properties, deposition parameters may be by changing one or more of (1) fiber material, (2) average fiber length, (3) average fiber diameter, (4) the mix of fiber sizes, (5) the standard deviation of fiber size distribution that are available for deposition, and (6) the quantity of fibers in solution that are available for co-deposition. In some embodiments, dispersion agents may be added to a co-deposition plating bath to inhibit entanglement and agglomeration of nano-fibers so as to improve uniformity of nano-fiber distribution. In some embodiments, functionalization of the fibers may be used to modify the fiber-metal interface and to improve suspension properties of the fibers while in solution and thus to improve co-deposition rates of the fibers.

Modulation or changing of these parameters may occur in different ways. For example, different plating baths with different fiber properties may be used during formation of different layers or different portions of a single layer. Different amounts, or locations, of agitation or stirring of the plating solution may be used to provide a desired level of fiber suspension in a region of the plating solution from which deposition will occur. Performing plating operations during or after movement of a substrate, or partially formed part, on to which plating will occur, to different locations in a plating bath that have different amounts of suspended fibers or different types of suspended fibers may be used to cause different amounts of co-deposition or co-deposition that results in different properties in the deposited materials. In some embodiments, co-deposition may provide a nano-fiber to metal mass ratio ranging from 0.4% or less to 7% or more or a nano-fiber to metal volume ratio ranging from about 3% to about 70%.

Even further modulation of material properties at different heights of a probe, probe preform, probes of a probe array, or preforms of a preform array, or other structure may occur by use of different plating parameters, current densities, temperatures, and the like, to achieve different co-deposition rates or combinations of co-deposition rates and grain size formation at different locations. Different material properties at different height levels of a plated material may be achieved by using different plating variations:
(1) Direct current plating with a current density that is fixed at any given time but is made to change from one value to another in a substantially discontinuous manner to cause relatively abrupt changes in grain size formation of deposited metals and thus changes in yield strength of the deposited metal at a given height of deposition. Times between current density changes may range from seconds to tens of seconds or even to minutes such that deposit thickness at any given current density ranges from tenths of microns, to microns, to tens of microns.
(2) Direct current plating with relatively slow transitions in current density from one value to another (i.e. from a local temporal minimum value to a local temporal maximum value, and vice-a-versa) where such transitions may occur over seconds, to tens of seconds, to even minutes uniformly in the transition between values.
(3) Pulsed current plating which has a first fast oscillation rate associated with the pulsing but a slower rate of change between changes to one or both of minimum and/or maximum current densities, or even duty cycle, to produce changes in material properties similar to those noted in (1) and (2) above. The fast oscillations may occur with a frequency range of 1 hz to 100 hz, or faster, and a duty cycle ranging from 5% to 95% with material property variations in resulting depositions occurring based on different frequencies and duties cycles which may deviate from properties resulting from a direct current deposition at a similar averaged current density. Though such high frequency pulsing variations may be used in some implementations of the present invention, since the variations of primary interest in the present application are those related to different regions of material that are each microns to tens of microns in height, it is the slower of rates of change between at least one of maximum current density, minimum current density and even applied duty cycle that may bring the types of changes in material properties that are of interest herein.
(4) Slow variations in reversed pulse plating parameters.
(5) Plating bath temperature.

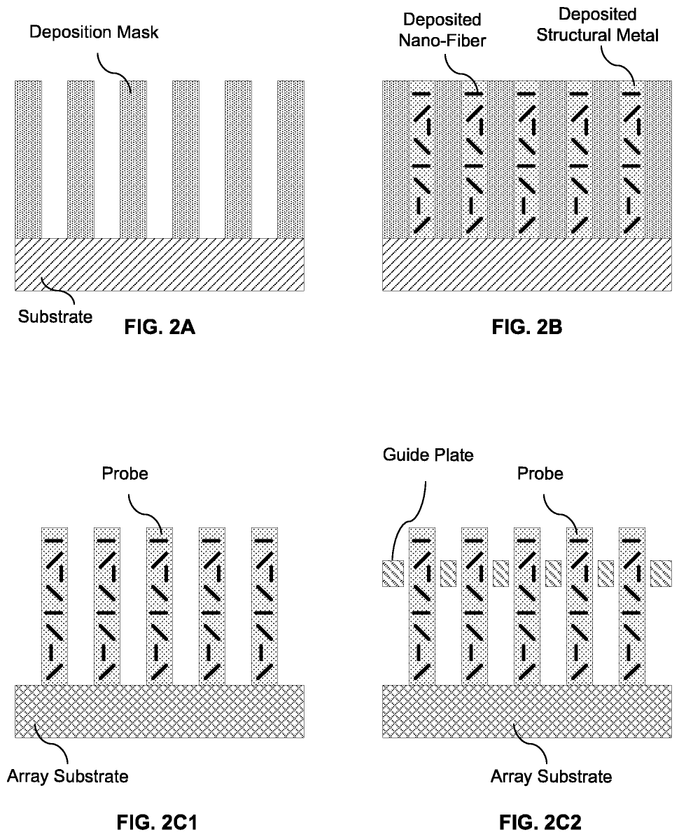

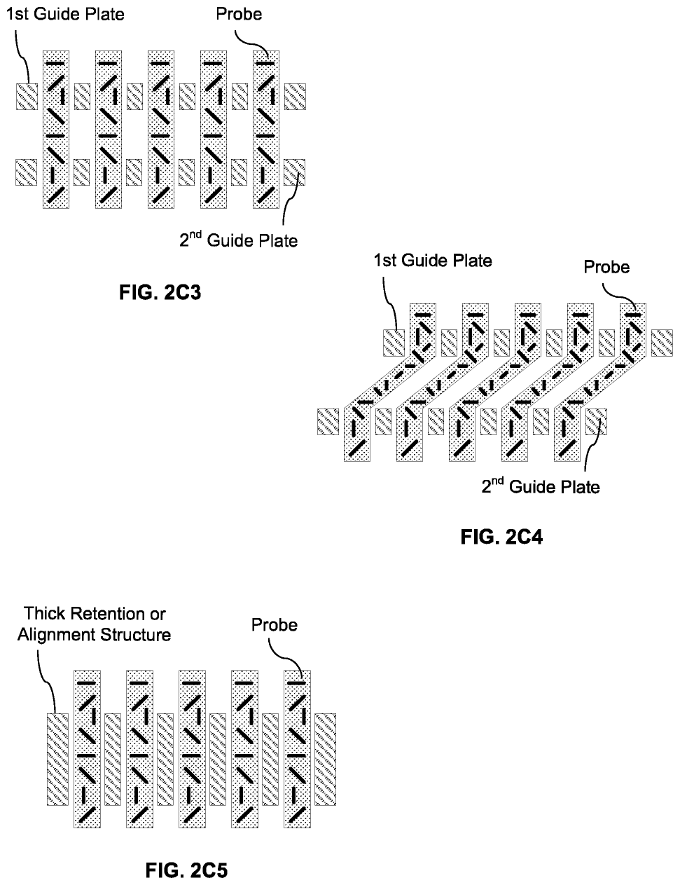

FIG. 2A provides a cut view of multiple openings in a photoresist that forms a plating template while FIG. 2B provides a cut view of the openings in the plating template and a composite material including co-plated metal and nano-fibers that form composite structures or portions of a composite structures (e.g. probes) wherein the plated material includes nano-fibers with a nominal diameter “d” and a length “L”.

FIGS. 2C1-2C5 illustrate side views of example probe arrays including probes of the type shown in FIG. 2B using different types of guide and/or mounting structures. FIG. 2C1 shows a plurality of example probes held in an array configuration by a permanent substrate that may or may not be a build substrate. FIG. 2C2 shows a plurality of example probes held in an array configuration by a combination of a permanent substrate and a guide plate. FIG. 2C3 shows example probes held in an array configuration by a plurality of guide plates. FIG. 2C4 shows example probes that have either been pre-shaped or shaped by relative lateral movement of the two guide plates of FIG. 2C3. FIG. 2C5 shows a plurality of probes held in an array configuration by a thick retention or alignment plate. Other example array embodiments are possible and will be apparent to those of skill in the art upon review of the teachings herein including the teachings incorporated herein by reference.

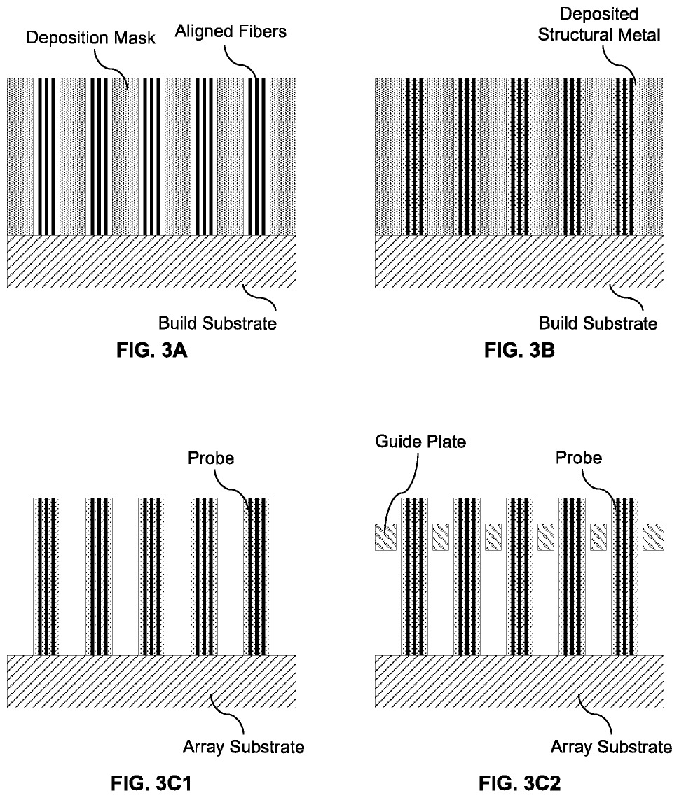

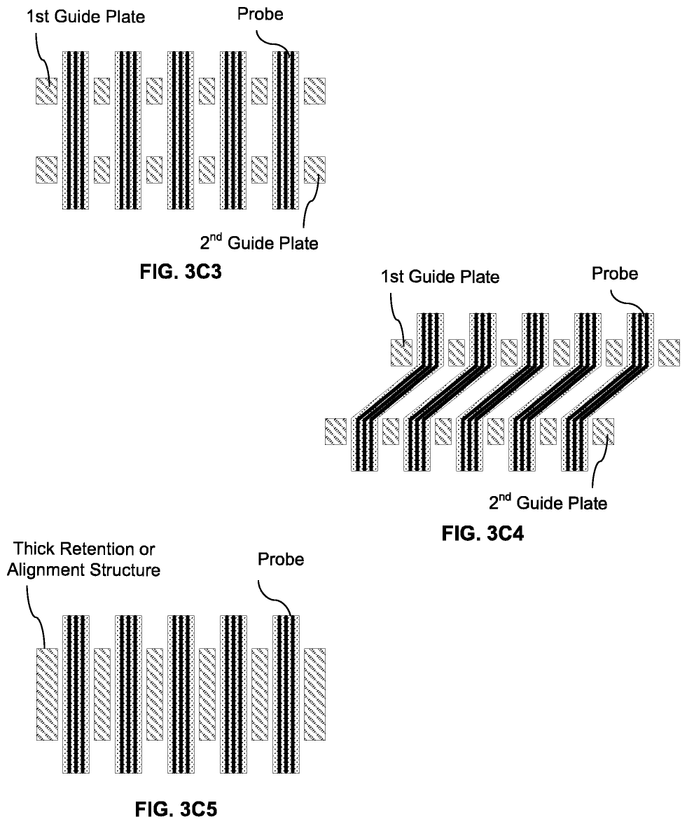

In a second group of embodiments, nano-fibers are first grown or positioned within an opening in a photoresist and a structural metal is plated into the opening to surround and encapsulate the fibers as shown in FIGS. 3A and 3B. FIG. 3A provides for the placement or creation of nano-particles within openings in a mask while FIG. 3B shows the state of the process after depositing metal (e.g. via electroplating) into the nano-fiber containing openings. As with the first embodiment, tuning of material properties may be further controlled by modulating the plating parameters and/or by controlling or modulating the fiber material or its properties (including, for example, the average fiber diameter, the density of the fibers, and the porosity between the fibers). In some embodiments, the photoresist template may be replaced by a different template material (e.g. a metallic sacrificial material). In some variations the nano-fibers may be located prior to formation of the masking material in either a selective manner or in a blank fashion with some of the fibers becoming hidden or buried by the masking material wherein such fibers may be removed along with the masking material after deposition of the structural metal.

FIGS. 3C1-3C5 illustrate side views of example probe arrays including probes of the type shown in FIG. 3B using different types of guide and/or mounting structures. FIG. 3C1 shows a plurality of example probes held in an array configuration by a permanent substrate that may or may not be a build substrate. FIG. 3C2 shows a plurality of example probes held in an array configuration by a combination of a permanent substrate and a guide plate. FIG. 3C3 shows example probes held in an array configuration by a plurality of guide plates. FIG. 3C4 shows example probes that have either been pre-shaped or shaped by relative lateral movement of the two guide plates of FIG. 3C3. FIG. 3C5 shows a plurality of probes held in an array configuration by a thick retention or alignment plate. Other example array embodiments are possible and will be apparent to those of skill in the art upon review of the teachings herein including the teachings incorporated herein by reference.

Variations of these first two embodiment groups are possible. In some embodiments, the deposited material may be planarized alone, as a combination of both metal and nano-fibers, or in combination with the photoresist or other masking or sacrificial material. In some embodiments, structures may be formed from single layers of combined nano-fibers and metal. In other embodiments, metal and nano-fiber structures may also include regions or metal without nano-fibers, dielectrics without nanofibers, and/or dielectrics with nanofibers.

In other alternatives, the single layer may form only a portion of a structure to be completed. In such alternatives, additional portions of the structure may be added or attached to the initial layer in any appropriate manner. For example, one or more additional portions of the structure may be formed by forming one or more additional layers on the already formed layer. The formation of the additional layer or layers may involve the use of the same or different structural materials, repeated use of the same cross-sectional configuration or different cross-sectional configurations, use of the same formation process or use of different formation processes. In some variations, the metal being deposited and/or the fiber located, created, or co-deposited may be modified one or more times prior to completing formation of the layer. In some embodiments, only a portion of the layers may include fibers as one of the structural materials or as part of the structural material. In some embodiments, the fibers may be part of layers that include structural dielectrics as opposed to or in addition to electroplated metals. In some embodiments, metal deposition may occur by a process other than electrodeposition (e.g. electroless deposition, vacuum or vapor deposition, and the like). In some alternatives, the fiber inclusion process of FIG. 2 may be used on one or more layers while the fiber inclusion process of FIGS. 3A & 3B may be used during the formation of one or more other layers. In some variations, after formation of a layer of the structure, portions of the plated structural metal (e.g. from the top 1-20% of the layer) may be removed by chemical or electrochemical etching leaving portions of the fiber exposed which can then be interlaced with fibers or metal or dielectrics forming part of a next portion of the structure (e.g. a next layer). In embodiments where planarization of layers is not to occur, instead of removing metal from one layer to allow interlacing to occur with a next layer, the fibers from the preceding layer may simply not be fully covered by metal deposited during formation of that layer leaving fibers available for interlacing with formation of a next layer.

In some alternatives, the photoresist may be replaced with a different material prior to creating, or locating the fibers and depositing the structural material(s), or co-depositing the fibers and other structural materials. In such cases, the original openings in the photoresist may be provided with a complementary pattern to that shown such that the photoresist openings receive a sacrificial material which is provided with second openings by removal of the photoresist which are of the desired pattern for receiving structural material. In some alternatives, the structure(s) may be formed on a permanent substrate (i.e. a substrate that will be included in the final product) or on a temporary substrate overlaid with a sacrificial or release layer or the temporary substrate may be a sacrificial substrate that will be destroyed when separated from the structure or structures. In some alternatives, the initial layer as illustrated might actually be something other than a first layer.

Numerous other variations of the above two embodiment groups are possible and include for example: (1) growing the vertically aligned fibers on a separate substrate and then transferring them into patterned areas of the substrate to be plated, (2) growing the vertically aligned fibers as a continuous film on a substrate, followed by photoresist application and patterning, then plating, and then removal of the fibers that are not encapsulated by structural material.

Embodiments of this invention can enable the use and implementation of selected plated materials for specific applications, such as very small pitch probing applications, by enabling the modulation of some of the material properties independently (e.g., elastic modulus independently of yield strength).

### Further Comments and Conclusions

Various other embodiments of the present invention exist. Some of these embodiments may be based on a combination of the teachings herein with various teachings incorporated herein by reference. For example, some other embodiments, or embodiment variations may be derived, mutatis mutandis, from the generalized embodiments, specific embodiments, and alternatives set forth in previously referenced U.S. Provisional Patent Application No. 63/015,450 (P-US390-A-MF) by Lockard, et al. and U.S. Provisional Patent Application No. 63/055,892 (P-US392-A-MF) by Yaglioglu.

For example, the guide plate to probe alignment and engagement methods of the '450 application may be used in aligning and engaging the deformation plates of the present invention. As another example, the guide plates of the '450 application that cause elastic deformation could function as deformation plates as taught in the present application wherein the plates may or may not be retained as guide plates (where any guide plate functionality may be used with or without implementing some additional amount of elastic or biased bending as taught in the '450 application). As another example, the deformation plates and variations associated with the embodiments of the '892 application may be used in variations of the embodiments of the present application, mutatis mutandis.

Some fabrication embodiments may not use any blanket deposition process. Some embodiments may use selective deposition processes or blanket deposition processes on some layers that are not electrodeposition processes. Some embodiments may use nickel or nickel-cobalt as a structural material while other embodiments may use different materials. For example, preferred spring materials include nickel (Ni), copper (Cu), beryllium copper (BeCu), nickel phosphorous (Ni—P), tungsten (W), aluminum copper (Al—Cu), steel, P7 alloy, palladium, palladium-cobalt, silver, molybdenum, manganese, brass, chrome, chromium copper (Cr—Cu), and combinations of these. Some embodiments may use copper as the structural material with or without a sacrificial material. Some embodiments, for example, may use nickel, nickel-phosphorous, nickel-cobalt, palladium, palladium-cobalt, gold, copper, tin, silver, zinc, solder, rhodium, rhenium as structural materials while other embodiments may use different materials. Some embodiments, for example, may use copper, tin, zinc, solder or other materials as sacrificial materials. Some embodiments may use different structural materials on different layers or on different portions of single layers. Some embodiments may remove a sacrificial material while other embodiments may not. Some embodiments may use photoresist, polyimide, glass, ceramics, other polymers, and the like as dielectric structural materials.

Structural or sacrificial dielectric materials may be incorporated into embodiments of the present invention in a variety of different ways. Such materials may form a third material or higher deposited material on selected layers or may form one of the first two materials deposited on some layers. Additional teachings concerning the formation of structures on dielectric substrates and/or the formation of structures that incorporate dielectric materials into the formation process and possibly into the final structures as formed are set forth in a number of patent applications filed Dec. 31, 2003: (1) U.S. Patent Application No. 60/534,184 (P-US032-A-SC), which is entitled “Electrochemical Fabrication Methods Incorporating Dielectric Materials and/or Using Dielectric Substrates”; (2) U.S. Patent Application No. 60/533,932 (P-US033-A-MF), which is entitled “Electrochemical Fabrication Methods Using Dielectric Substrates”; (3) U.S. Patent Application No. 60/534,157 (P-US041-A-MF), which is entitled “Electrochemical Fabrication Methods Incorporating Dielectric Materials”; (4) U.S. Patent Application No. 60/533,891 (P-US052-A-MF), which is entitled “Methods for Electrochemically Fabricating Structures Incorporating Dielectric Sheets and/or Seed layers That Are Partially Removed Via Planarization”; and (5) U.S. Patent Application No. 60/533,895 (P-US070-B-MF), which is entitled “Electrochemical Fabrication Method for Producing Multi-layer Three-Dimensional Structures on a Porous Dielectric”. These patent filings are each hereby incorporated herein by reference as if set forth in full herein.

Additional patent filings that provide, intra alia, teachings concerning incorporation of dielectrics into electrochemical fabrication processes include (1) U.S. patent application Ser. No. 11/139,262 (P-US144-A-MF), filed May 26, 2005, now U.S. Pat. No. 7,501,328, by Lockard, et al., and which is entitled “Methods for Electrochemically Fabricating Structures Using Adhered Masks, Incorporating Dielectric Sheets, and/or Seed Layers that are Partially Removed Via Planarization”; (2) U.S. patent application Ser. No. 11/029,216 (P-US128-A-MF), filed Jan. 3, 2005 by Cohen, et al., now abandoned, and which is entitled “Electrochemical Fabrication Methods Incorporating Dielectric Materials and/or Using Dielectric Substrates”; (3) U.S. patent application Ser. No. 11/028,957 (P-US127-A-SC), by Cohen, which was filed on Jan. 3, 2005, now abandoned, and which is entitled “Incorporating Dielectric Materials and/or Using Dielectric Substrates”; (4) U.S. patent application Ser. No. 10/841,300 (P-US099-A-MF), by Lockard et al., which was filed on May 7, 2004, now abandoned, and which is entitled “Methods for Electrochemically Fabricating Structures Using Adhered Masks, Incorporating Dielectric Sheets, and/or Seed Layers that are Partially Removed Via Planarization”; (5) U.S. patent application Ser. No. 10/841,378 (P-US106-A-MF), by Lembrikov et al., which was filed on May 7, 2004, now U.S. Pat. No. 7,527,721, and which is entitled “Electrochemical Fabrication Method for Producing Multi-layer Three-Dimensional Structures on a Porous Dielectric; (6) U.S. patent application Ser. No. 11/325,405 (P-US152-A-MF), filed Jan. 3, 2006 by Dennis R. Smalley, now abandoned, and entitled “Method of Forming Electrically Isolated Structures Using Thin Dielectric Coatings”; (7) U.S. patent application Ser. No. 10/607,931 (P-US075-A-MG), by Brown, et al., which was filed on Jun. 27, 2003, now U.S. Pat. No. 7,239,219, and which is entitled “Miniature RF and Microwave Components and Methods for Fabricating Such Components”, (8) U.S. patent application Ser. No. 10/841,006 (P-US104-A-MF), by Thompson, et al., which was filed on May 7, 2004, now abandoned, and which is entitled “Electrochemically Fabricated Structures Having Dielectric or Active Bases and Methods of and Apparatus for Producing Such Structures”; (9) U.S. patent application Ser. No. 10/434,295 (P-US061-A-MG), by Cohen, which was filed on May 7, 2003, now abandoned, and which is entitled “Method of and Apparatus for Forming Three-Dimensional Structures Integral With Semiconductor Based Circuitry”; and (10) U.S. patent application Ser. No. 10/677,556 (P-US081-A-MF), by Cohen, et al., filed Oct. 1, 2003, now abandoned, and which is entitled “Monolithic Structures Including Alignment and/or Retention Fixtures for Accepting Components”. These patent filings are each hereby incorporated herein by reference as if set forth in full herein.

Some embodiments may employ diffusion bonding or the like to enhance adhesion between successive layers of material. Various teachings concerning the use of diffusion bonding in electrochemical fabrication processes are set forth in U.S. patent application Ser. No. 10/841,382 (P-US102-A-SC), which was filed May 7, 2004 by Cohen et al., now abandoned, which is entitled “Method of Electrochemically Fabricating Multilayer Structures Having Improved Interlayer Adhesion” and which is hereby incorporated herein by reference as if set forth in full. This application is hereby incorporated herein by reference as if set forth in full.

The patent applications and patents set forth below are hereby incorporated by reference herein as if set forth in full. The teachings in these incorporated applications can be combined with the teachings of the instant application in many ways: For example, enhanced methods of producing structures may be derived from some combinations of teachings, enhanced structures may be obtainable, enhanced apparatus may be derived, enhanced methods of using may be implemented, and the like.

| U.S. patent application Ser. | |
|---|---|
| No., Filing Date | |
| U.S. App Pub No., Pub Date | |
| U.S. Pat. No., Pub Date | First Named Inventor, Title |
| 10/271,574 - Oct. 15, 2002 | Cohen, “Methods of and Apparatus for |
| 2003-0127336 - Jul. 10, 2003 | Making High Aspect Ratio |
| 7,288,178 - Oct. 30, 2007 | Microelectromechanical Structures” |
| 10/387,958 - Mar. 14, 2003 | Cohen, “Electrochemical Fabrication |
| 2003-022168 - Dec. 4, 2003 | Method and Application for Producing |
| -- | Three-Dimensional Structures Having |
| | Improved Surface Finish” |
| 10/434,289 - May 7, 2003 | Zhang, “Conformable Contact Masking |
| 2004-0065555 - Apr. 8, 2004 | Methods and Apparatus Utilizing In Situ |
| -- | Cathodic Activation of a Substrate” |
| 10/434,294 - May 7, 2003 | Zhang, “Electrochemical Fabrication |
| 2004-0065550 - Apr. 8, 2004 | Methods With Enhanced Post |
| -- | Deposition Processing” |
| 10/434,315 - May 7, 2003 | Bang, “Methods of and Apparatus for |
| 2003-0234179 - Dec. 25, 2003 | Molding Structures Using Sacrificial |
| 7,229,542 - Jun. 12, 2007 | Metal Patterns” |
| 10/434,494 - May 7, 2003 | Zhang, “Methods and Apparatus for |
| 2004-0000489 - Jan. 1, 2004 | Monitoring Deposition Quality During |
| -- | Conformable Contact Mask Plating |
| | Operations” |
| 10/677,498 - Oct. 1, 2003 | Cohen, “Multi-cell Masks and Methods |
| 2004-0134788 - Jul. 15, 2004 | and Apparatus for Using Such Masks To |
| 7,235,166 - Jun. 26, 2007 | Form Three-Dimensional Structures” |
| 10/697,597 - Oct. 29, 2003 | Lockard, “EFAB Methods and |
| 2004-0146650 - Jul. 29, 2004 | Apparatus Including Spray Metal or |
| -- | Powder Coating Processes” |
| 10/724,513 - Nov. 26, 2003 | Cohen, “Non-Conformable Masks and |
| 2004-0147124 - Jul. 29, 2004 | Methods and Apparatus for Forming |
| 7,368,044 - May 6, 2008 | Three-Dimensional Structures” |
| 10/724,515 - Nov. 26, 2003 | Cohen, “Method for Electrochemically |
| 2004-0182716 - Sep. 23, 2004 | Forming Structures Including Non- |
| 7,291,254 - Nov. 6, 2007 | Parallel Mating of Contact Masks and |
| | Substrates” |
| 10/830,262 - Apr. 21, 2004 | Cohen, “Methods of Reducing Interlayer |
| 2004-0251142 - Dec. 16, 2004 | Discontinuities in Electrochemically |
| 7,198,704 - Apr. 3, 2007 | Fabricated Three-Dimensional |
| | Structures” |
| 10/841,100 - May 7, 2004 | Cohen, “Electrochemical Fabrication |
| 2005-0032362 - Feb. 10, 2005 | Methods Including Use of Surface |
| 7,109,118 - Sep. 19, 2006 | Treatments to Reduce Overplating |
| | and/or Planarization During Formation |
| | of Multi-layer Three-Dimensional |
| | Structures” |
| 10/841,347 - May 7, 2004 | Cohen, “Multi-step Release Method for |
| 2005-0072681 - Apr. 7, 2005 | Electrochemically Fabricated |
| -- | Structures” |
| 10/949,744 - Sep. 24, 2004 | Lockard, “Multi-Layer Three- |
| 2005-0126916 - Jun. 16, 2005 | Dimensional Structures Having Features |
| 7,498,714 - Mar. 3, 2009 | Smaller Than a Minimum Feature Size |
| | Associated with the Formation of |
| | Individual Layers” |
| 12/345,624 - Dec. 29, 2008 | Cohen, “Electrochemical Fabrication |
| -- | Method Including Elastic Joining of |
| 8,070,931 - Dec. 6, 2011 | Structures” |
| 14/194,564 - Feb. 28, 2014 | Kumar, “Methods of Forming Three- |
| 2014-0238865 - Aug. 28, 2014 | Dimensional Structures Having Reduced |
| 9,540,233 - Jan. 10, 2017 | Stress and/or Curvature” |
| 14/720,719 - May 22, 2015 | Veeramani, “Methods of Forming Parts |
| -- | Using Laser Machining” |
| 9,878,401 - Jan. 30, 2018 | |
| 14/872,033 - Sep. 30, 2015 | Le, “Multi-Layer, Multi-Material |
| -- | Microscale and Millimeter Scale Batch |
| -- | Part Fabrication Methods Including |
| | Disambiguation of Good Parts and |
| | Defective Parts” |

It will be understood by those of skill in the art that additional operations may be used in variations of the above presented method of making embodiments. These additional operations may, for example, perform cleaning functions (e.g. between the primary operations discussed herein or discussed in the various materials incorporated herein by reference, they may perform activation functions and monitoring functions, and the like.

It will also be understood that the probe elements of some aspects of the invention may be formed with processes which are very different from the processes set forth herein and it is not intended that structural aspects of the invention need to be formed by only those processes taught herein or by processes made obvious by those taught herein.

Though various portions of this specification have been provided with headers, it is not intended that the headers be used to limit the application of teachings found in one portion of the specification from applying to other portions of the specification. For example, alternatives acknowledged in association with one embodiment, are intended to apply to all embodiments to the extent that the features of the different embodiments make such applications functional and do not otherwise contradict or remove all benefits of the adopted embodiment. Various other embodiments of the present invention exist. Some of these embodiments may be based on a combination of the teachings set forth herein with various teachings incorporated herein by reference.

It is intended that any aspects of the invention set forth herein represent independent invention descriptions which Applicant contemplates as full and complete invention descriptions that Applicant believes may be set forth as independent claims without need of importing additional limitations or elements, from other embodiments or aspects set forth herein, for interpretation or clarification other than when explicitly set forth in such independent claims once written. It is also understood that any variations of the aspects set forth herein represent individual and separate features that may form separate independent claims, be individually added to independent claims, or added as dependent claims to further define an invention being claimed by those respective dependent claims should they be written.

In view of the teachings herein, many further embodiments, alternatives in design and uses of the embodiments of the instant invention will be apparent to those of skill in the art. As such, it is not intended that the invention be limited to the particular illustrative embodiments, alternatives, and uses described above but instead that it be solely limited by the claims presented hereafter.

1. A probe, comprising:
(a) an elastically deformable body portion having a first end and a second end;
(b) a first contact region connected directly or indirectly to the first end; and
(c) a second contact region connected directly or indirectly to the second end;
wherein the elastically deformable body portion comprises a plurality of nano-fibers embedded in a structural metal to form a composite material.

2. The probe of claim 1 wherein the nano-fibers comprise a material selected from a group consisting of: (1) metal nanorods, (2) nanotubes, and (3) carbon nanotubes.

3. The probe of claim 1 comprising a plurality of adhered layers.

4. The probe of claim 1 wherein the first contact region is configured for a function selected from a group consisting of: making temporary pressure based electrical contact to a first electronic component upon elastically biasing the elastically deformable body portion with the first contact region against the first electronic component, and (2) bonding to the first electronic component for making permanent contact.

5. The probe of claim 4 wherein the first contact region is configured for bonding to the first electronic component for making permanent contact.

6. The probe of claim 4 wherein the first contact region is configured for making temporary contact.

7. The probe of claim 1 wherein the second contact region is configured for making temporary pressure based electrical contact to a second electronic component upon elastically biasing the elastically deformable body portion with the second contact region against the second electronic component.

8. A probe array, comprising:
(a) a plurality of probes, comprising:
(i) an elastically deformable body portion having a first end and a second end;
(ii) a first contact region connected directly or indirectly to the first end; and
(iii) a second contact region connected directly or indirectly to the second end,
wherein the elastically deformable body portion comprises a plurality of nano-fibers embedded in a structural metal, and
(b) at least one probe array retention structure to hold the probes in a desired probe array configuration.

9. The probe array of claim 8, wherein the at least one probe array retention structure is selected from a group consisting of:
(i) a substrate to which the first contact regions of the probes are bonded at a plurality of bonding locations;
(ii) a substrate to which the first contact regions of the probes are bonded along with at least one guide plate having a plurality of holes which engage the probes wherein the holes in the guide plate are laterally aligned with bonding locations on the substrate;
(iii) a substrate to which the first contact regions of the probes are bonded along with at least one guide plate having a plurality of holes which engage the probes wherein the holes in at least one of the at least one guide plate are laterally shifted relative to the bonding locations on the substrate;
(iv) a plurality of guide plates, each having a plurality of holes which engage the probes;
(v) a plurality of guide plates, each having a plurality of holes which engage the probes, wherein at least two of the plurality of guide plates have holes engaging probes that are laterally aligned;
(vi) a plurality of guide plates, each having a plurality of holes which engage the probes, wherein at least two of the plurality of guide plates have holes engaging probes that are laterally shifted with respect to one another; and
(vii) a retention plate having a plurality of retention holes into which the probes are inserted.

10. The probe array of claim 9, wherein the at least one probe array retention structure is a retention plate which has thickness selected from a group consisting of: (1) at least ¼ of a longitudinal length of the probes from first contact region to second contact region; (2) at least ½ of a longitudinal length of the probes from first contact region to second contact region; (3) at least ¾ of a longitudinal length of the probes from first contact region to second contact region.

11. The probe array of claim 8 wherein the nano-fibers in the elastically deformable body portion of the probes comprise a material selected from a group consisting of: (1) metal nanorods, (2) nanotubes, and (3) carbon nanotubes.

12. The probe array of claim 8, wherein the probes comprise a plurality of adhered layers.

13. The probe array of claim 8 wherein the first contact region of the probes is configured for a function selected from a group consisting of: (1) making temporary pressure based electrical contact to a first electronic component upon elastically biasing the elastically deformable body portion with the first contact region against the first electronic component, and (2) bonding to the first electronic component for making permanent contact.

14. The probe array of claim 12 wherein the first contact region of the probes is configured for bonding to the first electronic component for making permanent contact.

15. The probe array of claim 12 wherein the first contact region of the probes is configured for making temporary contact.

16. The probe array of claim 8 wherein the second contact region of the probes is configured for making temporary pressure based electrical contact to a second electronic component upon elastically biasing the elastically deformable body portion with the second contact region against the second electronic component.

17. A method of forming a probe array, comprising:
(a) forming a plurality of probes, each having an elastically deformable body portion a first contact region and a second contact region, the elastically deformable body portion having a first end and a second end connected directly or indirectly to the first contact region and the second contact region, respectively;
(b) providing an array substrate;
(c) providing at least one probe array retention structure to hold the probes in a desired configuration of the probe array;
wherein forming of the probes comprises forming the elastically deformable body of each probe by a composite material comprising a plurality of nano-fibers and at least one structural metal.

18. The method of claim 17, wherein forming the plurality of probes comprises:
(i) providing a probe substrate; and
(ii) forming a plating template with a plurality of openings wherein the probes are formed,
(iii) forming the composite material of the probes selected from a group consisting of:
(A) simultaneously co-depositing a plurality of nano-fibers and at least one structural metal into the plurality of openings;
(B) simultaneously co-depositing a plurality of nano-fibers and at least one structural metal into the plurality of openings of the plating template, wherein fiber properties within a plating solution are maintained at a uniform level during the co-depositing to provide uniform properties to the resulting composite material;
(C) simultaneously co-depositing a plurality of nano-fibers and at least one structural metal into the plurality of openings of the plating template, wherein fiber properties within a plating solution are varied during the co-depositing to cause varying properties within the resulting composite material;
(D) locating a plurality of nano-fibers into the plurality of openings of the plating template and thereafter depositing at least one structural metal into the plurality of openings of the plating template;
(E) locating a plurality of longitudinally oriented nano-fibers into the plurality of openings of the plating template and thereafter depositing at least one structural metal into the plurality of openings of the plating template;
(F) growing a plurality of nano-fibers in the plurality of openings of the plating template and thereafter depositing at least one structural metal into the plurality of openings of the plating template;
(G) growing a plurality of longitudinally oriented nano-fibers in the plurality of openings of the plating template and thereafter depositing at least one structural metal into the plurality of openings of the plating template.

19. The method of claim 18, further comprising (H) planarizing the deposited material.

20. The method of claim 17, wherein forming the plurality of probes comprises:
(i) providing a probe substrate;
(ii) providing a plurality of nano-fibers directly or indirectly on the probe substrate;
(iii) forming a patterned plating template with a plurality of openings that contains the plurality of nano-fibers;
(iv) depositing at least one structural metal into the plurality of openings of the plating template, and
(v) removing the plating template along with at least a portion of any nano-fibers that are not held by the structural metal as deposited.

21. The method of claim 20, wherein providing the plurality of nano-fibers is selected from a group consisting of:
(A) locating a plurality of nano-fibers directly or indirectly on a probe substrate;
(B) locating a plurality of longitudinally oriented nano-fibers directly or indirectly on the probe substrate;
(C) growing a plurality of nano-fibers directly or indirectly on the probe substrate; and
(D) growing a plurality of longitudinally oriented nano-fibers directly or indirectly on the probe substrate.

22. The method of claim 20, further comprising (E) planarizing the deposited material.

23. The method of claim 18, wherein providing at least one probe array retention structure is selected from a group consisting of:
(i) bonding the first contact region of the probes at a plurality of boding location of the array substrate, wherein the array substrate comprises the probe substrate being a build substrate; and
(ii) bonding the first contact regions of the probes at a plurality of boding location of the array substrate, wherein the array substrate and the probe substrate being a build substrate are different.

24. The method of claim 23, further comprising a step selected from a group consisting of:
(iii) providing at least one guide plate having a plurality of holes that engage the probes;
(iv) providing at least one guide plate having a plurality of holes and inserting the probes into the plurality of holes that are laterally aligned with bonding locations on the array substrate;
(vi) providing at least one guide plate having a plurality of holes and inserting the probes into the plurality of holes, and laterally shifting the at least one guide plate and the array substrate so that the plurality of holes in the at least one guide plate are laterally shifted with respect to bonding locations on the array substrate;
(vii) providing a plurality of guide plates, each having a plurality of holes which engage the probes;
(viii) providing a plurality of guide plates, each having a plurality of holes which engage the probes, wherein at least one of the plurality of guide plates has a plurality of holes engaging probes that are laterally aligned;
(ix) providing a plurality of guide plates, each having a plurality of holes which engage the probes, wherein at least two of the plurality of guide plates have respective plurality of holes engaging probes that are laterally aligned with respect to one another;
(ix) providing a plurality of guide plates, each having a plurality of holes which engage the probes, wherein at least two of the plurality of guide plates have respective plurality of holes engaging probes that are laterally shifted with respect to one another;
(x) providing a retention plate with a plurality of retention holes for receiving probes and inserting the probes into the plurality of retention holes;
(xi) providing a retention plate with a plurality of retention holes for receiving probes and inserting the probes into the plurality of retention holes, wherein the retention plate has a thickness selected from a group consisting of: (1) at least ¼ of a longitudinal length of the probes; (2) at least ½ of a longitudinal length of the probes; (3) at least ¾ of a longitudinal length of the probes, the longitudinal length of the probes being a length from the first contact region to the second contact region thereof.

25. The method of claim 18, wherein nano-fibers are provided selected from a group consisting of: (1) metal nanorods, (2) nanotubes, and (3) carbon nanotubes.
